(19) United States
(12) Patent Application Publication
(10) Pub. No.: US 2011/0088764 A1
(43) Pub. Date: Apr. 21, 2011

(54) SOLAR CELL AND MANUFACTURING METHOD THEREOF

(75) Inventor: Chin-Yao TSAI, Tainan (TW)

(73) Assignee: AURIA SOLAR CO., LTD., Sinshih Township Tainan (TW)

(21) Appl. No.: 12/980,233

(22) Filed: Dec. 28, 2010

(30) Foreign Application Priority Data
Dec. 29, 2009 (TW) 098145634

(51) Int. Cl. H01L 31/06; H01L 31/18

(52) U.S. Cl. 136/255; 438/95; 257/E31.029

(57) ABSTRACT

A solar cell including a substrate, a first conductive layer, a photovoltaic layer, a second conductive layer and at least one passivation layer is provided. The first conductive layer is disposed on the substrate. The photovoltaic layer generates electron-hole pairs after receiving light, wherein the photovoltaic layer is disposed on the first conductive layer and has a plurality of doped films. The second conductive layer is disposed on the photovoltaic layer. The passivation layer is disposed onto at least one of the positions between the first conductive layer and the photovoltaic layer, between the doped films within the photovoltaic layer, and between the photovoltaic layer and the second conductive layer, so as to reduce the chance for the electron-hole pairs resulting in recombination on at least one of the surfaces of the photovoltaic layer. A manufacturing method of the solar cell is also provided.

### CROSS-REFERENCES TO RELATED APPLICATIONS

This application claims priority to Taiwan Patent Application No. 098145634 filed on Dec. 29, 2009, which is hereby incorporated by reference in its entirety.

### BACKGROUND OF THE INVENTION

1. Field of the Invention

The present invention relates to a solar cell and a manufacturing method thereof, and more particularly, to a solar cell with an improved photo-electric conversion efficiency and a manufacturing method thereof.

2. Descriptions of the Related Art

With rising of the environmental protection awareness, the concept of “energy saving and carbon dioxide emission reduction” is gradually receiving more and more attention. Accordingly, exploitation and use of renewable energy sources have become a focus of development all over the world. Among the renewable energy sources, solar cells that are capable of converting the solar energy into the electric energy are considered to be the most promising, so numerous manufacturers are now devoted to production of solar cells. Currently, a critical problem related to solar cells is how to improve the photo-electric conversion efficiency thereof, and any improvement in the photo-electric conversion efficiency of solar cells will lead to improvement in competitive edge of the solar cell products.

FIG. 1 is a schematic view of a conventional solar cell. Referring to FIG. 1, the solar cell 100 comprises a substrate 110, a first conductive layer 120, a photovoltaic layer 130 and a second conductive layer 140. The photovoltaic layer 130 has, for example, a P-type doped film 132 and an N-type doped film 134.

Generally, when a light ray L from the outside is irradiated onto the solar cell 100, electron-hole pairs will be generated by the P-type doped film 132 and the N-type doped film 134 in response to the light ray. Under action of a built-in electric field formed by a p-n junction, the electrons and the holes migrate towards the first conductive layer 120 and the second conductive layer 140 respectively to form a photocurrent. This results in an electric energy storage status. Then if a load circuit or an electronic device is externally connected across the solar cell, the electric energy can be supplied to drive the load circuit or the electronic device.

However, because the P-type doped film 132 or the N-type doped film 134 has a high concentration of defects, the electron-hole pairs tend to experience surface recombination near an interface 133 between the P-type doped film 132 and the N-type doped film 134. Similarly, at an interface 125 between the photovoltaic layer 130 and the first conductive layer 120 or at an interface 133 between the photovoltaic layer 130 and the second conductive layer 140, the electron-hole pairs also tend to experience surface recombination. When surface recombination of the electron-hole pairs occurs in the solar cell 100, energy of the light ray L absorbed by the photovoltaic layer 130 is converted from the electric energy into heat energy and dissipated. This leads to a degraded photo-electric conversion efficiency of the solar cell 100.

### SUMMARY OF THE INVENTION

In view of this, the present invention provides a solar cell, which has an improved photo-electric conversion efficiency by reducing the chance of surface recombination of the electron-hole pairs.

The present invention also provides a method for manufacturing a solar cell, with which the aforesaid solar cell can be manufactured.

The solar cell of the present invention comprises a substrate, a first conductive layer, a photovoltaic layer, a second conductive layer and at least one passivation layer. The first conductive layer is disposed on the substrate. The photovoltaic layer is adapted to generate electron-hole pairs when being irradiated by a light ray. The photovoltaic layer is disposed on the first conductive layer and has a plurality of doped films. The second conductive layer is disposed on the photovoltaic layer. The at least one passivation layer is disposed on at least one of the positions between the first conductive layer and the photovoltaic layer, between the doped films in the photovoltaic layer and between the photovoltaic layer and the second conductive layer, so as to reduce the chance of surface recombination of the electron-hole pairs on at least one surface of the photovoltaic layer.

In an embodiment of the present invention, the doped films include a P-type doped film and an N-type doped film, and the doped films are stacked on the first conductive layer.

In an embodiment of the present invention, the P-type doped film is disposed between the first conductive layer and the N-type doped film, or the N-type doped film is disposed between the first conductive layer and the P-type doped film.

In an embodiment of the present invention, the doped films include a plurality of P-type doped films and a plurality of N-type doped films. Each of the P-type doped films and each of the N-type doped films are stacked on the first conductive layer alternately to form a plurality of p-n junctions.

In an embodiment of the present invention, the photovoltaic layer further comprises at least one intrinsic layer disposed between parts of the doped films.

In an embodiment of the present invention, when the at least one passivation layer is disposed between the doped films in the photovoltaic layer, the P-type doped films are disposed between the at least one passivation layer and the at least one intrinsic layer or the N-type doped films are disposed between the at least one passivation layer and the at least one intrinsic layer.

In an embodiment of the present invention, the at least one passivation layer is made of silicon oxide (SiOₓ), silicon nitride (SiNₓ), silicon oxynitride (SiNOₓ) or a combination thereof.

In an embodiment of the present invention, the at least one passivation layer is made of an intrinsic semiconductor material.

In an embodiment of the present invention, the at least one passivation layer has a thickness of 1 Å to 10000 Å.

In an embodiment of the present invention, the at least one passivation layer has a thickness of 10 Å to 1000 Å.

In an embodiment of the present invention, the photovoltaic layer is made of a group IV element semiconductor thin film, a group III-V compound semiconductor thin film, a group II-VI compound semiconductor thin film, an organic compound semiconductor thin film, or a combination thereof.

In an embodiment of the present invention, the group IV element semiconductor thin film comprises at least one of a carbon element thin film, a silicon element thin film, a germanium elemental thin film, a silicon carbide thin film and a germanium silicide thin film, or a combination thereof in a monocrystalline phase, a polycrystalline phase, an amorphous phase or a microcrystalline phase.

In an embodiment of the present invention, the group III-V compound semiconductor thin film comprises at least one of a gallium arsenide (GaAs) compound thin film, an indium gallium phosphide (InGaP) compound thin film, or a combination thereof.

In an embodiment of the present invention, the group II-VI compound semiconductor thin film comprises at least one of a copper indium selenium (CIS) compound thin film, a copper indium gallium selenium (CIGS) compound thin film and a cadmium telluride (CdTe) compound thin film, or a combination thereof.

In an embodiment of the present invention, the organic compound semiconductor thin film comprises a mixture of a conjugated polymer donor and a carbon nanosphere acceptor.

In an embodiment of the present invention, the first conductive layer is made of a transparent conductive layer while the second conductive layer comprises at least one of a reflective layer and a transparent conductive layer; or the second conductive layer is made of a transparent conductive layer while the first conductive layer comprises at least one of a reflective layer and a transparent conductive layer.

The method for manufacturing a solar cell of the present invention comprises the following steps: providing a substrate; forming a first conductive layer on the substrate; forming, on the first conductive layer, a photovoltaic layer having a plurality of doped films, wherein the photovoltaic layer generates electron-hole pairs when being irradiated by a light ray; forming a second conductive layer on the photovoltaic layer; and forming a passivation layer on at least one of the positions between the first conductive layer and the photovoltaic layer, between the doped films in the photovoltaic layer and between the photovoltaic layer and the second conductive layer, so as to reduce the chance of surface recombination of the electron-hole pairs on at least one surface of the photovoltaic layer.

In an embodiment of the present invention, step of forming the passivation layer comprises forming a native oxide on at least one of the first conductive layer and the second conductive layer.

In an embodiment of the present invention, the native oxide is silicon oxide (SiOₓ).

In an embodiment of the present invention, the step of forming the passivation layer comprises performing a CO₂ plasma process or a deposition process.

In an embodiment of the present invention, the deposition process comprises a plasma enhanced chemical vapor deposition (PECVD) process, a radio frequency plasma enhanced chemical vapor deposition (RF PECVD) process, a very high frequency plasma enhanced chemical vapor deposition (VHF PECVD) process or a microwave plasma enhanced chemical vapor deposition (MW PECVD) process.

According to the above descriptions, the solar cell of the present invention has at least one passivation layer disposed on at least one of the positions between the first conductive layer and the photovoltaic layer, between the doped films in the photovoltaic layer and between the photovoltaic layer and the second conductive layer. This can reduce the chance of surface recombination of the electron-hole pairs to result in an improved photo-electric conversion efficiency of the solar cell. Furthermore, a method for manufacturing a solar cell is also disclosed in the present invention, with which the aforesaid solar cell can be manufactured.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIG. 1 is a schematic view of a conventional solar cell;

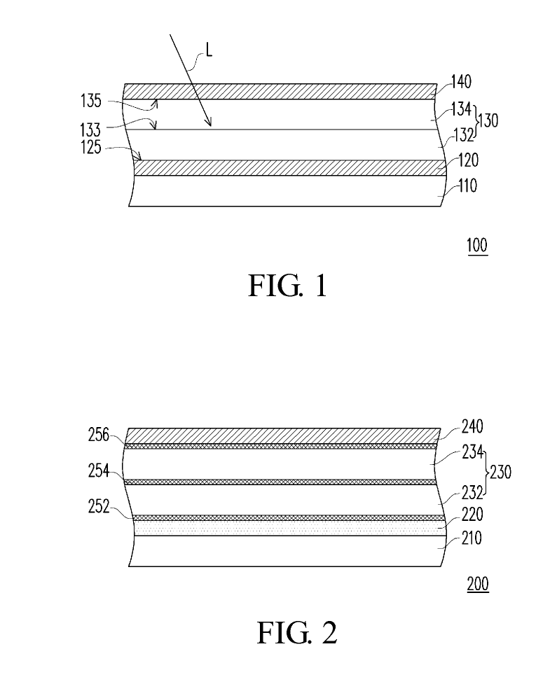

FIG. 2 is a schematic view of a solar cell according to an embodiment of the present invention;

FIG. 3 is a schematic view of a solar cell according to another embodiment of the present invention;

FIG. 4 is a schematic view of a solar cell according to a further embodiment of the present invention; and

FIGS. 5A to 5H illustrate a process of manufacturing a solar cell according to an embodiment of the present invention.

### DESCRIPTION OF THE PREFERRED EMBODIMENT

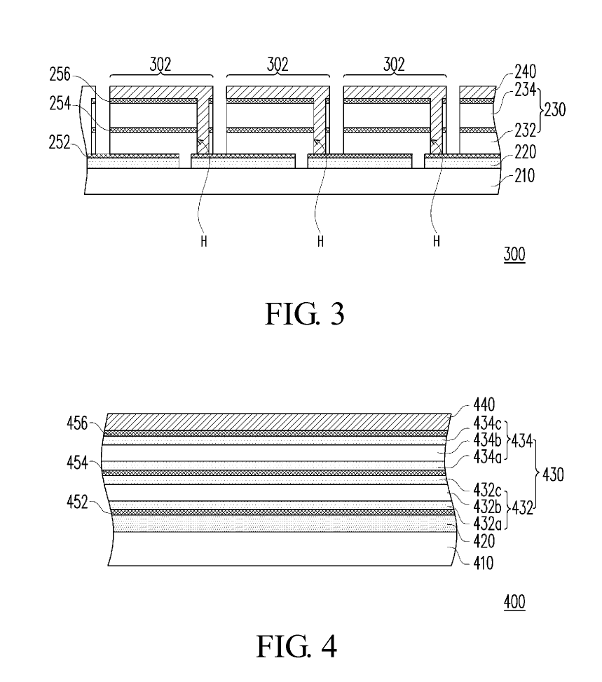

FIG. 2 is a schematic view of a solar cell according to an embodiment of the present invention. Referring to FIG. 2, the solar cell 200 comprises a substrate 210, a first conductive layer 220, a photovoltaic layer 230, a second conductive layer 240 and passivation layers 252, 254, 256. In this embodiment, the substrate 210 is, for example, a transparent substrate such as a glass substrate.

The first conductive layer 220 is disposed on the substrate 210. In this embodiment, the first conductive layer 220 is a transparent conductive layer, which may be made of at least one of zinc oxide, tin oxide, indium tin oxide (ITO), indium zinc oxide (IZO), indium tin zinc oxide (ITZO), aluminum tin oxide (ATO), aluminum zinc oxide (AZO), cadmium indium oxide (CIO), cadmium zinc oxide (CZO), gallium zinc oxide (GaZO) and tin oxyfluoride.

The photovoltaic layer 230 generates electron-hole pairs when being irradiated by a light ray. The photovoltaic layer 230 is disposed on the first conductive layer 220 and has a P-type doped film 232 and an N-type doped film 234. That is, the structure of film of the photovoltaic layer 230 is a photo-electric conversion structure of a p-n junction design. In another embodiment that is not shown, the structure of film of the photovoltaic layer 230 may also be a photo-electric conversion structure of a p-i-n junction design, which is comprised of a P-type semiconductor layer, an intrinsic layer and an N-type semiconductor layer.

In this embodiment, the P-type doped film 232 and the N-type doped film 234 are stacked on the first conductive layer 220, with the P-type doped film 232 being interposed between the first conductive layer 220 and the N-type doped film 234. Alternatively, in other embodiments, the structure of film of the photovoltaic layer 230 may also have the N-type doped film interposed between the first conductive layer and the P-type doped film.

In this embodiment, films of the photovoltaic layer 230 may be semiconductor thin films formed of a group IV element such as carbon, silicon or germanium, for example, at least one of a carbon element thin film, a silicon element thin film, a germanium element thin film, a silicon carbide thin film and a germanium silicide thin film or a combination thereof in a monocrystalline phase, a polycrystalline phase, an amorphous phase or a microcrystalline phase. In an embodiment, apart from being made of silicon thin films, the photovoltaic layer 230 may also be made of at least one of copper indium gallium selenium (CIGS) and cadmium telluride (CdTe), or a combination thereof, in which case the solar cell 200 of this embodiment will become a CIGS solar cell or a CdTe solar cell.

In another embodiment, the photovoltaic layer 230 may also be made of a material selected from a group III-V compound semiconductor thin film, a group II-VI compound semiconductor thin film, an organic compound semiconductor thin film, or a combination thereof. For example, the group III-V compound semiconductor thin film includes at least one of a gallium arsenide (GaAs) compound thin film and an indium gallium phosphide (InGaP) compound thin film, or a combination thereof. The group II-VI compound semiconductor thin film comprises at least one of a copper indium selenium (CIS) compound thin film, a copper indium gallium selenium (CIGS) compound thin film and a cadmium telluride (CdTe) compound thin film, or a combination thereof. The organic compound semiconductor thin film comprises a mixture of a conjugated polymer donor and a carbon nanosphere acceptor.

Referring also to FIG. 2, the second conductive layer 240 is disposed on the photovoltaic layer 230. The second conductive layer 240 may be made of a material described with reference to the aforesaid transparent conductive layer, so no further description will be made thereon herein. In this embodiment, the first conductive layer 220 and the second conductive layer 240 are, for example, both transparent conductive layers. In another embodiment not shown, the second conductive layer 240 may also be a stack formed by a reflective layer and the aforesaid transparent conductive layer. The reflective layer may be disposed between the transparent conductive layer and the substrate 210, and be made of a metal with desirable reflectivity such as aluminum (Al), silver (Ag), molybdenum (Mo) or copper (Cu). In other words, the design in terms of this may be varied depending on different requirements of users (e.g., depending on whether the solar cell to be fabricated is to receive light on both surfaces or on only a single surface), and what described above is only for illustration purpose but is not to limit the present invention.

The passivation layer 252 is disposed between the first conductive layer 220 and the photovoltaic layer 230, the passivation layer 254 is disposed between the P-type doped film 232 and the N-type doped film 234 in the photovoltaic layer 230, and the passivation layer 252 is disposed between the photovoltaic layer 230 and the second conductive layer 240 with an aim to reduce the chance of recombination of the electron-hole pairs on surfaces of the photovoltaic layer 230. In detail, it is likely that dangling bonds exist on interfaces between the layers 220, 230, 240 or defects (e.g., dislocations, grain boundaries, and point defects) exist in these layers per se. Through disposition of the passivation layers 252, 254, 256 between the layers 220, 230, 240, the number of the dangling bonds on the interfaces or the defects in the surfaces of these layers can be decreased. Thus, the chance that the electrons and holes experience recombination on the surfaces of the layers 220, 230 and 240 gets lowered because the electrons and holes will not be bonded to such dangling bonds or defects. It shall be noted that, although the solar cell is shown to have three passivation layers 252, 254, 256 located at different positions, this is only shown for illustration purpose and the present invention has no limitation on the number of the passivation layers. In other embodiments, there may be disposed only one or two of the passivation layers 252, 254, 256 depending on requirements in practical use.

In this embodiment, the passivation layers 252, 254, 256 may be made of silicon oxide (SiOₓ), silicon nitride (SiNₓ), silicon oxynitride (SiNOₓ) or a combination thereof. In another embodiment, the passivation layers 252, 254, 256 may also be made of an intrinsic semiconductor material. It shall be appreciated that, albeit of the aforesaid benefits provided by the passivation layers 252, 254, 256, too thick passivation layers may increase the electrical resistance of the solar cell. Therefore, it is important to choose appropriate thicknesses of the passivation layers, and the thicknesses may vary depend on materials of the passivation layers. In this embodiment, the passivation layers 252, 254, 256 may have a thickness of 1 Å to 10000 Å. More particularly, in a preferred embodiment, the passivation layers 252, 254, 256 may have a thickness of 10 Å to 1000 Å, which can effectively improve the electrical performance of the solar cell 200.

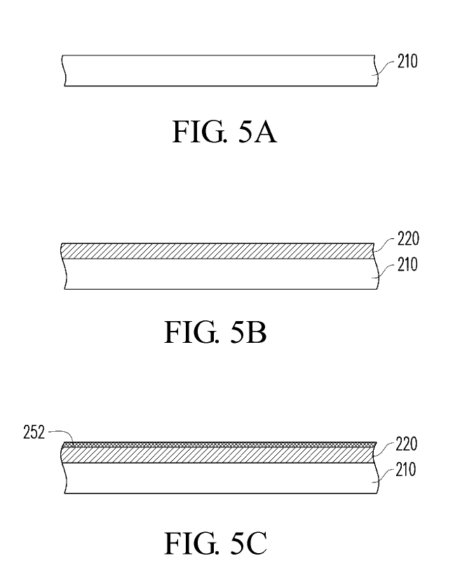

FIG. 3 is a schematic view of a solar cell according to another embodiment of the present invention. Referring to FIG. 3, the solar cell 300 comprises all the members of the aforesaid solar cell 200. For these identical members, they will be denoted with identical reference numerals and will not be further described again herein.

Particularly, the solar cell 300 is of a solar cell structure comprised of a plurality of sub-cells 302 in electrical tandem with each other. The second conductive layer 240 of each of the sub-cells 302 is electrically connected with the first conductive layer 220 of an adjacent sub-cell 302 through an opening H. With the passivation layers 252, 254, 256 disposed therein, the solar cell 300 can also achieve the same objectives and functionalities as the solar cell 200.

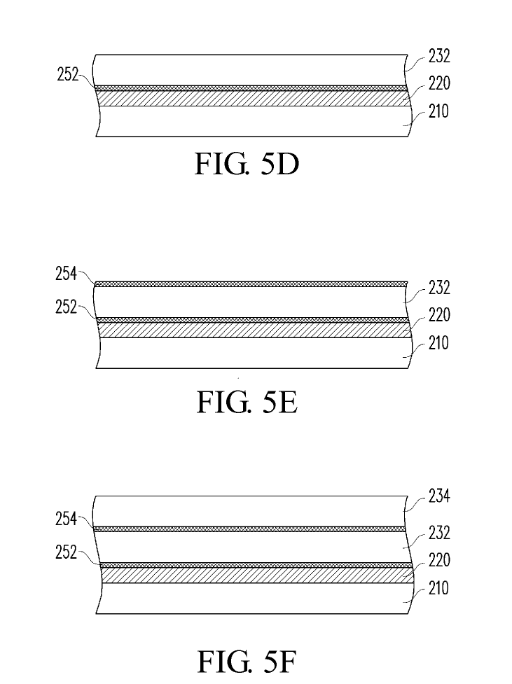

FIG. 4 is a schematic view of a solar cell according to a further embodiment of the present invention. Referring to FIG. 4, the solar cell 400 comprises a substrate 410, a first conductive layer 420, a photovoltaic layer 430, a second conductive layer 440 and passivation layers 452, 454, 456.

The first conductive layer 420 is disposed on the substrate 410. The photovoltaic layer 430 generates electron-hole pairs when being irradiated by a light ray. The photovoltaic layer 430 is disposed on the first conductive layer 420 and has a plurality of doped films. In this embodiment, the photovoltaic layer 430 may have a first photovoltaic sub-layer 432 and a second photovoltaic sub-layer 434. For example, the first photovoltaic sub-layer 432 is made of an amorphous silicon thin film and the second photovoltaic sub-layer 434 is made of a microcrystalline silicon thin film. In other embodiments, the photovoltaic layer 430 may also be a stack structure comprised of three or more sub-layers; and what described above is only for illustration purpose and the present invention has no limitation on the number of the photovoltaic sub-layers in the solar cell.

The first photovoltaic sub-layer 432 comprises, for example, a P-type doped film 432a, an intrinsic layer 432b and an N-type doped film 432c. The second photovoltaic sub-layer 434 comprises, for example, a P-type doped film 434a, an intrinsic layer 434b and an N-type doped film 434c. In other words, the first photovoltaic sub-layer 432 and the second photovoltaic sub-layer 434 of the photovoltaic layer 430 are in electrical tandem with each other to form a tandem junction structure. Particularly, the P-type doped films 432a, 434a and the N-type doped films 432c, 434c are, for example, alternately stacked on the first conductive layer 420 to form a plurality of p-n junctions. In some embodiments, the first photovoltaic sub-layer 432 may also not be provided with the intrinsic layer 432b, or the second photovoltaic sub-layer 434 may not be provided with the intrinsic layer 434b. In other words, one of the first photovoltaic sub-layer 432 and the second photovoltaic sub-layer 434 may be a photo-electric conversion structure of a p-n junction design, while the other may be a photo-electric conversion structure of a p-i-n junction design.

The second conductive layer 440 is disposed on the photovoltaic layer 430. The passivation layer 452 is disposed between the first conductive layer 420 and the photovoltaic layer 430, the passivation layer 454 is disposed between the N-type doped film 432c of the first photovoltaic sub-layer 432 and the P-type doped film 434a of the second photovoltaic sub-layer 434, and the passivation 456 is disposed between the photovoltaic layer 430 and the second conductive layer 440 with an aim to reduce the chance of surface recombination of the electron-hole pairs on at least one surface of the photovoltaic layer 430. Similarly, in other embodiments of the solar cell, there may be disposed only one or two of the passivation layers 452, 454, 456.

In this embodiment, the passivation layers 452, 454, 456 are disposed, for example, between the plurality of doped films of the photovoltaic layer 430. More specifically, the P-type doped film 432a of the first photovoltaic sub-layer 432 is disposed between the passivation layer 452 and the intrinsic layer 432b, and the P-type doped film 434a of the second photovoltaic sub-layer 434 is disposed between the passivation layer 454 and the intrinsic layer 434b. Additionally, the N-type doped film 432c of the first photovoltaic sub-layer 432 is disposed between the passivation layer 454 and the intrinsic layer 432b, and the N-type doped film 434c of the second photovoltaic sub-layer 434 is disposed between the passivation layer 456 and the intrinsic layer 434b. With the passivation layers 452, 454, 456 disposed therein, the solar cell 400 can also achieve the same objectives and functionalities as the solar cell 200.

As can be known from the above embodiments, solar cells where a passivation layer(s) is disposed between a conductive layer and a photovoltaic layer or between a plurality of doped films of the photovoltaic layer to reduce the chance of surface recombination of electron-hole pairs shall all fall within the spirits and scope of the present invention.

Hereinbelow, a method for manufacturing the solar cell 200 will be described.

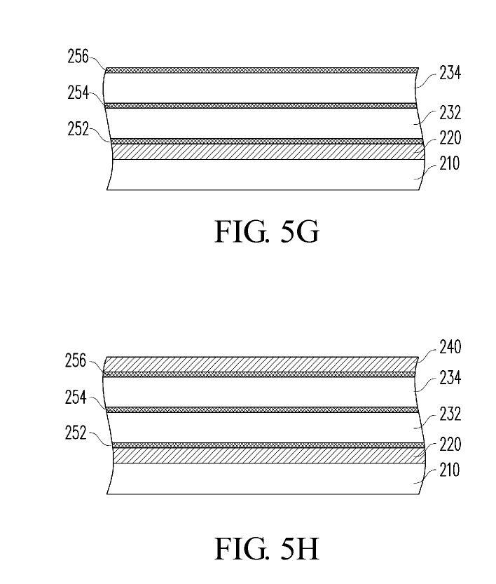

FIGS. 5A to 5H illustrate a process of manufacturing a solar cell according to an embodiment of the present invention. Firstly, referring to FIG. 5A, a substrate 210 is provided. For example, the substrate 210 is a glass substrate.

Then, referring to FIG. 5B, a first conductive layer 220 is formed on the substrate 210. In this embodiment, the first conductive layer 220 may be the aforesaid transparent conductive layer and formed through, for example, a sputtering process, a metal organic chemical vapor deposition (CVD) process or an evaporation process.

Next, referring to FIG. 5C, a passivation layer 252 is formed on the first conductive layer 220. In this embodiment, the passivation layer 252 may be formed by, for example, leaving the first conductive layer 220 still in the air for a period of time to form a native oxide. In another embodiment, the passivation layer 252 may also be formed by performing a CO₂ plasma process to form a SiOₓ thin film on the first conductive layer 220, or by performing a deposition process to form an intrinsic silicon thin film on the first conductive layer 220. Here, the deposition process may be a plasma enhanced chemical vapor deposition process, a radio frequency plasma enhanced chemical vapor deposition (RF PECVD) process, a very high frequency plasma enhanced chemical vapor deposition (VHF PECVD) process or a microwave plasma enhanced chemical vapor deposition (MW PECVD) process.

Subsequently, referring to FIG. 5D, a P-type doped film 232 is formed on the passivation layer 252. In this embodiment, the P-type doped film 232 is formed by, for example, performing the aforesaid deposition process on the passivation layer 252 to form an amorphous silicon or microcrystalline silicon thin film and then, or in-situ, performing a doping process to introduce a P-type dopant into the amorphous silicon or microcrystalline silicon thin film. The P-type dopant is, for example, a group III element. More specifically, the doping process may be performed by an in-situ doping during deposition or by a furnace diffusion unit or an ion implantation unit.

Thereafter, referring to FIG. 5E, a passivation layer 254 is formed on the P-type doped film 232. In this embodiment, the passivation layer 254 may be formed by, for example, forming a native oxide on the P-type doped film 232. The native oxide may be, for example, silicon oxide. Alternatively, the passivation layer 254 may be formed in other ways as described with reference to the passivation layer 252.

Next, referring to FIG. 5F, an N-type doped film 234 is formed on the passivation layer 254. Here, the way in which the N-type doped film 234 is formed is substantially similar to that of the P-type doped film 232. For example, the deposition process as described above is performed on the passivation layer 254 to form an amorphous silicon or microcrystalline silicon thin film, and then, or at the same time, a doping process is performed to introduce an N-type dopant into the amorphous silicon or microcrystalline silicon thin film. The N-type dopant is, for example, a group V element.

Afterwards, referring to FIG. 5G, a passivation layer 256 is formed on the N-type doped film 234. In this embodiment, the way in which the passivation layer 256 is formed is substantially similar to those of the passivations 252, 254, so no further description will be made thereon again.

Finally, referring to FIG. 5H, a second conductive layer 240 is formed on the passivation layer 256. In this embodiment, the second conductive layer 240 is formed through, for example, the sputtering process, the MOCVD process or the evaporation process described above and is made of, for example, the aforesaid transparent conductive layer. Hence, this will not be further described again herein. Thus, the process of manufacturing the solar cell 200 shown in FIG. 2 is completed.

It shall be emphasized that, the aforesaid manufacturing method is only described as an example, and in some embodiments, the chance of recombination of the electron-hole pairs on the surfaces of the photovoltaic layer 230 may also be reduced by selectively forming only one or two of the passivation layer 252 between the first conductive layer 220 and the photovoltaic layer 230, the passivation layer 254 between the P-type doped film 232 and the N-type doped film 234 and the passivation layer 256 between the photovoltaic layer 230 and the second conductive layer 240. Furthermore, in other possible embodiments, a solar cell where the photovoltaic layer is of a tandem junction structure, a triple junction structure or has more than three junctions may also be manufactured through a manufacturing method similar to what described above.

As described above, because the solar cell of the present invention has a passivation layer(s) disposed on at least one of the positions between the conductive layers and the photovoltaic layer and between the plurality of doped films, the chance of surface recombination of the electron-hole pairs gets reduced. In other words, the solar cell of the present invention can present an improved photo-electric conversion efficiency. In addition, the method for manufacturing a solar cell of the present invention can form the passivation layer(s) in the solar cell through a simplified process, thereby improving the performance of the resulting solar cell.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A solar cell, comprising:
a substrate;
a first conductive layer disposed on the substrate;
a photovoltaic layer for generating electron-hole pairs when being irradiated by a light ray, wherein the photovoltaic layer is disposed on the first conductive layer and has a plurality of doped films;
a second conductive layer disposed on the photovoltaic layer; and
at least one passivation layer, disposed on at least one of the positions between the first conductive layer and the photovoltaic layer, between the doped films in the photovoltaic layer and between the photovoltaic layer and the second conductive layer, so as to reduce the chance of surface recombination of the electron-hole pairs on at least one surface of the photovoltaic layer.

2. The solar cell as claimed in claim 1, wherein the doped films include a P-type doped film and an N-type doped film, and the doped films are stacked on the first conductive layer.

3. The solar cell as claimed in claim 2, wherein the P-type doped film is disposed between the first conductive layer and the N-type doped film, or the N-type doped film is disposed between the first conductive layer and the P-type doped film.

4. The solar cell as claimed in claim 2, wherein the photovoltaic layer further comprises an intrinsic layer disposed between the P-type doped film and the N-type doped film.

5. The solar cell as claimed in claim 1, wherein the doped films include a plurality of P-type doped films and a plurality of N-type doped films, each of the P-type doped films and each of the N-type doped films are stacked on the first conductive layer alternately to form a plurality of p-n junctions, the photovoltaic layer further comprises at least one intrinsic layer disposed between some of the doped films, and when the at least one passivation layer is disposed between the doped films in the photovoltaic layer, the P-type doped films are disposed between the at least one passivation layer and the at least one intrinsic layer or the N-type doped films are disposed between the at least one passivation layer and the at least one intrinsic layer.

6. The solar cell as claimed in claim 1, wherein the at least one passivation layer is made of silicon oxide (SiOₓ), silicon nitride (SiNₓ, silicon oxynitride (SiNOₓ), or a combination thereof.

7. The solar cell as claimed in claim 1, wherein the at least one passivation layer is made of an intrinsic semiconductor material.

8. The solar cell as claimed in claim 1, wherein the at least one passivation layer has a thickness of 1 Å to 10000 Å.

9. The solar cell as claimed in claim 1, wherein the photovoltaic layer is made of a group IV element semiconductor thin film, a group III-V compound semiconductor thin film, a group II-VI compound semiconductor thin film, an organic compound semiconductor thin film, or a combination thereof.

10. The solar cell as claimed in claim 9, wherein the group IV element semiconductor thin film comprises at least one of a carbon element thin film, a silicon element thin film, a germanium elemental thin film, a silicon carbide thin film and a germanium silicide thin film, or a combination thereof in a monocrystalline phase, a polycrystalline phase, an amorphous phase or a microcrystalline phase.

11. The solar cell as claimed in claim 9, wherein the group III-V compound semiconductor thin film comprises at least one of a gallium arsenide (GaAs) compound thin film and an indium gallium phosphide (InGaP) compound thin film, or a combination thereof.

12. The solar cell as claimed in claim 9, wherein the group II-VI compound semiconductor thin film comprises at least one of a copper indium selenium (CIS) compound thin film, a copper indium gallium selenium (CIGS) compound thin film and a cadmium telluride (CdTe) compound thin film, or a combination thereof.

13. The solar cell as claimed in claim 9, wherein the organic compound semiconductor thin film comprises a mixture of a conjugated polymer donor and a carbon nanosphere acceptor.

14. The solar cell as claimed in claim 1, wherein the first conductive layer is made of a transparent conductive layer while the second conductive layer comprises at least one of a reflective layer and a transparent conductive layer, or the second conductive layer is made of a transparent conductive layer while the first conductive layer comprises at least one of a reflective layer and a transparent conductive layer.

15. A method for manufacturing a solar cell, comprising:
providing a substrate;
forming a first conductive layer on the substrate;
forming, on the first conductive layer, a photovoltaic layer having a plurality of doped films, wherein the photovoltaic layer generates electron-hole pairs when being irradiated by a light ray;
forming a second conductive layer on the photovoltaic layer; and
forming a passivation layer on at least one of the positions between the first conductive layer and the photovoltaic layer, between the doped films in the photovoltaic layer and between the photovoltaic layer and the second conductive layer, so as to reduce the chance of surface recombination of the electron-hole pairs on at least one surface of the photovoltaic layer.

16. The method for manufacturing a solar cell as claimed in claim 15, wherein forming the passivation layer comprises forming a native oxide on at least one of the first conductive layer and the second conductive layer.

17. The method for manufacturing a solar cell as claimed in claim 15, wherein the native oxide is silicon oxide (SiOₓ).

18. The method for manufacturing a solar cell as claimed in claim 15, wherein forming the passivation layer comprises performing a CO₂ plasma process or a deposition process.

19. The method for manufacturing a solar cell as claimed in claim 18, wherein the deposition process comprises a plasma enhanced chemical vapor deposition (PECVD) process, a radio frequency plasma enhanced chemical vapor deposition (RF PECVD) process, a very high frequency plasma enhanced chemical vapor deposition (VHF PECVD) process or a microwave plasma enhanced chemical vapor deposition (MW PECVD) process.
